(19) United States
(12) Patent Application Publication
(10) Pub. No.: US 2025/0010409 A1
(43) Pub. Date: Jan. 9, 2025

(54) Conductive Compositions For Low Temperature Assembly Of Electronic Components

(71) Applicant: ORMET CIRCUITS, INC., SAN DIEGO, CA (US)

(72) Inventors: YANRONG SHI, SAN DIEGO, CA (US); SHENGYI LI, SAN DIEGO, CA (US); MATTHEW WROSCH, ESCONDIDO, CA (US); CATHERINE SHEARER, SAN MARCOS, CA (US)

(21) Appl. No.: 18/712,634

(22) PCT Filed: Nov. 18, 2022
(86) PCT No.: PCT/US2022/080176

§ 371 Date: May 22, 2024

Related U.S. Application Data
(60) Provisional application No. 63/282,604, filed on Nov. 23, 2021.

(51) Int. Cl. B23K 35/02; B23K 35/26; B23K 35/362; B23K 101/36

(52) U.S. Cl. CPC B23K 35/025; B23K 35/262; B23K 35/362; B23K 2101/36

(57) ABSTRACT

To provide a composition for electromagnetic wave shield capable of forming a sintered compact for electromagnetic wave shield excellent in electromagnetic wave shield effect. SOLUTION: A composition for electromagnetic wave shield includes: a metal particle A, a metal particle B with a lower fusion point than the metal particle A; a metal particle C which includes a metal composition contained in the metal particle B and is an alloy particle with a lower fusion point than the metal particle B; and resin. Between the metal particle A, the metal particle B and the metal particle C, transient liquid phase sintering is possible.

### CROSS-REFERENCE TO RELATED APPLICATIONS

This application claims priority to U.S. Provisional Patent application No. 63/282,604 filed on Nov. 23, 2021, which is hereby incorporated by reference.

### BACKGROUND OF THE INVENTION

The present disclosure relates to metal compositions, methods of preparation and uses thereof. More specifically, the present disclosure relates to conductive metal compositions utilizing a combination of metal particulate fillers.

The electronics industry has continually driven towards higher performance and functionality in smaller form factors. These driving forces have translated into smaller circuit features, designs and manufacturing methods that support more efficient circuit routing, elimination of layers of packaging, integration of multiple components into a single electronic package, and sophisticated engineered materials. Issues that have been exacerbated by these trends include thermal management and management of the thermo-mechanical stresses generated by close juxtaposition of dissimilar materials.

One example is the packaging of semiconductor processors, in which multiple semiconductor die components and passive components are integrated into a single large package. In addition, structures to provide mechanical stability and thermal management as well as extensive circuit routing to spread the chip-level interconnect points to a pattern compatible with the circuit geometries on the motherboard are also incorporated. The plethora of materials in such a package—as well as within the receiving motherboard—frequently result in warpage that can be exacerbated with the application of heat such as would be encountered in the assembly operation of the package to the motherboard. If the package and/or the motherboard are warped, there is significant risk that the lack of coplanarity will result in poor or non-existent electrical interconnections formed between the two during the assembly operation. Reducing the process temperature for the assembly operation can thus mitigate this significant risk by reducing the warpage of both the package and motherboard.

An impediment to the adoption of a low temperature assembly process is the materials currently compatible with such a process. Thermosetting adhesives passively loaded with conductive fillers lack the electrical and thermal performance and reliability for high performance computing. Low melting solder alloy materials offer acceptable performance but have the potential to remelt in operation or in the common thermal cycle reliability tests in which the upper temperature bound is in the same range as the assembly temperatures contemplated.

Transient liquid phase sintering (TLPS) is a technology that could be employed to resolve these problems. In TLPS paste compositions, there is a mixture of metallic particles of two different Types. The first Type of particle becomes liquid at, or near, the assembly process temperature and contains an element that is reactive with an element in the second Type of particle. The second Type of particle does not become liquid as the assembly process temperature. At the assembly process temperature, the reactive element(s) in the first particle Type interdiffuse and react rapidly with the reactive elements of the second particle Type, thus resulting in consumption of the reactive elements in the first particle Type due to the formation of new reaction products. The resultant reaction products have melting temperatures in excess of the assembly process temperature.

TLPS paste compositions can be processed like conventional solder paste and form robust metallurgical junctions to solder wettable surfaces, but, unlike solder, these compositions essentially create a metal “thermoset” during processing. This “thermosetting” characteristic is advantageous because the paste materials can be used to effect low temperature assembly without the liability of re-melt at the original process temperature.

In prior art TLPS compositions, the first particle Type typically comprises alloys of tin and the second particle Type typically comprises one or more of copper, silver, and nickel. In these compositions tin serves as the reactive element in the first Type of particle and is reactive with copper, silver, and nickel to form crystalline intermetallics with melting points far in excess of the process temperature. Commonly, the tin is alloyed with one or more additional elements to provide a reduced process temperature, improved wetting of the surfaces to be joined or improved mechanical characteristics.

For a low assembly temperature process, suitable alloying elements to depress the melt temperature of the tin would include indium and bismuth. For example, tin has a melting point of 232° C., but through the formation of a binary alloy with indium or bismuth the melting temperature of the resultant alloy can be reduced to 118° C. and 138° C. respectively, depending on the composition. Additional alloying elements, in small proportions, may further depress the melting point.

The electronics packaging industry has designated process temperatures at or below 140° C. as very low temperature assembly process. To achieve high flow of the molten alloy and ensure a robust joint, typically the melting temperature of the alloy should be at least 10° C. below the process temperature. Therefore, SnBi eutectic alloy, at 138° C., is not suitable for very low temperature assembly. Conversely, SnIn eutectic alloy, at 118° C., has a melting temperature too low to withstand typical industry thermal cycling requirements which have an upper temperature bound of 125° C.

Both In and Bi suffer from additional deleterious characteristics. In is expensive and is an extremely reactive metal that forms a range of reaction products with the active elements in the Type 2 particles, some of which have low melting points and poor mechanical characteristics. Bi is brittle and an extremely poor thermal and electrical conductor.

It would be advantageous if the industry need for a very low temperature assembly process could be met by combining the low melting temperature of SnIn alloy with the reduced expense of a SnBi alloy in a TLPS paste composition that mitigated the deleterious characteristics of these two alloy families by replacing some of the particle composition with Type 2 particles comprising Cu, Ag, Ni and combinations thereof to effect reaction products with melting temperatures in excess of the process temperature.

### BRIEF SUMMARY OF THE INVENTION

The present claims are directed to compositions of metallic particles that can be processed at temperatures at or below 140° C., with a high specificity of metallurgical component selection, as well as the resultant intermetallic products and interconnected networks thereof. The present compositions have high tolerance to thermo-mechanical stress and possess thermally stable bulk and interfacial electrical and thermal resistance. The present compositions may additionally comprise organic compounds that are application-specific to the adherends and surrounding materials.

Presently disclosed compositions comprise a mixture of metal particles of two types, Type 1, which is liquid or semi-liquid at the process temperature and Type 2, which is not liquid at the process temperature. In the presently disclosed compositions, specific metallic elements contained within the Type 1 and Type 2 particles undergo reactions analogous to organic chemistry reactions. How the metallic reagents are introduced, the proportion of metallic reagents, and the presence of other metallic species, even in very small quantities, has a substantial impact on the products of the reaction. The metallic products formed by reaction of the present compositions include both alloys (solid solutions) and intermetallics (crystalline structures with specific proportions of elements). Much as reagents in organic chemistry are often introduced with facilitating groups (e.g., leaving groups such as halogens or para-toluenesulfonate), Type 1 particles may comprise facilitating metal elements in addition to the primary metal element reagent. Also, like organic reactions, some compositions of the present application employ metal elements that create a catalytic effect on the metal reactions.

Metallic elements in the present compositions that undergo reactions to form intermetallic species are designated by terms metal Reagent A, present in the Type 1 particles, and metal Reagent B, present in the Type 2 particles. In the practice, the Type 1 particles become liquid or semi-liquid so that liquid Reagent(s) A may participate in liquid-solid interdiffusion with Reagent(s) B resulting in metallic solutions and intermetallic crystals that are solid at process temperature T1. The liquification or near-liquification of the Type 1 particles at T1 is enabled by one or more alloying metallic elements that are designated Facilitators. Facilitator elements facilitate the liquid-solid interdiffusion by depressing the melting point of the Type 1 particles, such that at least a portion of the Type 1 particles is liquid at process temperature T1. Both Type 1 particles and Type 2 particles may contain additional elements other than the Reagent and Facilitator elements.

In some embodiments of the composition, Type 1 particles comprising Reagent A are introduced to the composition in two readily differentiated sets. Type 1A particles are characterized as being fully liquid at T1 whereas Type 1B particles are characterized as being fully liquid at a temperature less than T1+100° C.

More specifically, in some embodiments, compositions are provided that include a mixture of particles, comprising between about 1 mass % and about 10 mass % of Type 1A particles, comprising at least one Reagent A; between about 50 mass % and about 80 mass % of Type 1B particles comprising at least one Reagent A; between about 5 mass % and about 45 mass % of Type 2 particles comprising at least one Reagent B; and an organic vehicle.

In some embodiments, either Type 1A, or Type 1B or both Type 1A and Type 1B particles may further comprise at least one Facilitator element; wherein said Facilitator element(s) in Type 1A particles may differ from the Facilitator element(s) in Type 1B particles by either elemental type and/or proportion.

In certain aspects of the instant disclosure, Reagent A and Reagent B react at T1 to form metallic solutions and intermetallic crystals that are solid at T1. In other aspects of the compositions, Reagent A further reacts with surfaces comprising the elements selected from the group consisting of Sn, Ag, Au, Ni, Pd and Cu to create metallic joints to such surfaces.

Also provided by the present disclosure are solid solution and intermetallic products formed from the present compositions by thermal process processing at a temperature between about 80° C. and 150° C.

Further provided are methods for fabricating the composition of the present disclosure by combining a predetermined ratio of Type 1A particles, Type 1B particles, Type 2 particles, and the organic vehicle to form a mixture of components, wherein the organic vehicle holds the particles together in a mixture and typically comprises a flux. The organic vehicle may also contain resins, polymers, reactive monomers, volatile solvents, and other fillers.

The present disclosure also provides methods for making an electrically and thermally conductive interconnections by applying an amount of the particle mixture compositions described herein to an assembly of at least two parts, where the at least two parts are to be electrically joined together, heating the composition to a temperature T1, wherein T1 is between about 80° C. and about 150° C., wherein the Reagent A and Reagent B in the composition react to form an solid solutions and intermetallics, wherein the solid solution(s) and intermetallic(s) products are electrically and thermally conductive. In some embodiments of the present disclosure, the solid solutions and intermetallic species have a melting temperature that is at least 10° C. higher than the processing temperature T1.

### BRIEF DESCRIPTION OF SEVERAL VIEWS OF THE DRAWINGS

The accompanying drawings, which are included to provide a further understanding of the disclosed subject matter and are incorporated in and constitute a part of this specification, illustrate embodiments of the disclosed subject matter and together with the description serve to explain the principles of the disclosed subject matter. In the drawings:

FIG. 1 is a cross-sectional optical image of an embodiment composition connecting a ball-grid-array (BGA) electronic package to an electronic substrate with copper terminations.

FIG. 2 and FIG. 3 are x-ray images of large-scale semiconductor packages attached to substrates in a 140° C. process using compositions of the embodiment shown in FIG. 1.

FIG. 4A and FIG. 4B are cross section views of assemblies as-processed and after an additional reflow cycle, respectively.

### DETAILED DESCRIPTION OF THE INVENTION

It is to be understood that both the foregoing general description and the following detailed description are exemplary and explanatory only and are not restrictive of the claimed subject matter. As used herein, the use of the singular includes the plural unless specifically stated otherwise.

As used herein, “or” means “and/or” unless stated otherwise. Furthermore, use of the term “including” as well as other forms, such as “includes,” and “included,” is understood as “comprising” and is not limiting. The section headings used herein are for organizational purposes only and are not to be construed as limiting the subject matter described.

Whenever it appears herein, a numerical range of integer value such as “1 to 20” refers to each integer in the given range; e.g., “1 to 20 percent” means that the percentage can be 1%, 2%, 3%, etc., up to and including 20%. Where a range described herein includes decimal values, such as “1.2% to 10.5%”, the range refers to each decimal value of the smallest increment indicated in the given range; e.g., “1.2% to 10.5%” means that the percentage can be 1.2%, 1.3%, 1.4%, 1.5%, etc. up to and including 10.5%; while “1.20% to 10.50%” means that the percentage can be 1.20%, 1.21%, 1.22%, 1.23%, etc. up to and including 10.50%.

### Terms, Definitions, and Abbreviations

The term “about” as used herein means that a number referred to as “about” comprises the recited number plus or minus 1-10% of that recited number. For example, “about” 100 degrees can mean 95-105 degrees or as few as 99-101 degrees depending on the situation.

The term “alloy” refers to a mixture containing two or more metals, and optionally additional non-metals, where the elements of the alloy are fused together or dissolving into each other when molten. Alloy compositions referenced in the present disclosure are defined by the weight percentages of the constituent elements.

“Flux” as used herein, refers to a substance, often an acid or base, that to promote fusing of metals and in particular, removes and prevents the formation of metal oxides.

The term “liquidus temperature” as used herein, refer to the temperature (a point) at which a solid becomes a liquid at atmospheric pressure.

The term “Type 1A particles” as used herein, refers to metallic particles having a liquidus temperature that is equal to, or lower than, about 150° C.

The term “Type 1B particles” as used herein, refers to metallic particles having a liquidus temperature that is below about 250° C.

The term “Type 2 particles,” as used herein, refers to a metal having the liquidus temperature that is higher than about 550° C.

The term “Facilitator,” as used herein, refers to an element that may be alloyed with Reagent A in particle Type 1A, or Type 1B to reduce the liquidus temperature of the particles.

The term “eutectic” refers to a mixture or an alloy in which the constituent parts are present in such proportions that the melting point is as low as possible, the constituents melting simultaneously. Accordingly, a eutectic alloy or mixture liquefies at a single temperature.

The term “non-eutectic” refers to a mixture or an alloy that does not possess eutectic properties. Accordingly, when a non-eutectic alloy liquefies, its components liquefy at different temperatures, exhibiting a melting range that extends below the liquidus temperature.

The term “differential scanning calorimetry” (“DSC”) refers to a method of thermal analysis in which the difference in the amount of heat required to increase the temperature of a sample and reference are measured as a function of temperature.

The term “sintering” refers to a process in which adjacent surfaces of metal powder particles are bonded by heating. “Liquid phase sintering” refers to a form of sintering in which the solid powder particles coexist with a liquid phase. Densification and homogenization of the mixture occur as the metals diffuse into one another and form new alloy and/or intermetallic species.

The term “transient liquid phase sintering” or “TLPS,” with the reference to powders, describes a process in which the liquid only exists for a short period of time as a result of the homogenization of the metals to form a mixture of solid alloy and/or intermetallic species. The liquid phase has a very high solubility in the surrounding solid phase, thus diffusing rapidly into the solid and eventually solidifying. Diffusional homogenization creates the final composition without the need to heat the mixture above its equilibrium melting temperature.

The term “processing temperature” or “T1” refers to a temperature at which Reagent A and Reagent B (both of which are described and discussed in detail below in the application) react to form solid solution and intermetallic species.

The terms “intermetallics” or “intermetallic species” refer to a solid material, which is comprised of two or more metal atoms in a certain proportion, that has a definite structure which differs from those of its constituent metals.

The term “bulk resistivity” refers to the inherent electrical resistance of a material “in bulk,” i.e., regardless of the shape or size.

The term “substantially,” as used herein, refers to a proportion high than 90 weight percent of a given species.

In TLPS compositions comprising powder metallurgy, particles comprising Reagent A and Reagent B are admixed. As the temperature is raised to the to the processing temperature T1, at least one particle type comprising Reagent A becomes liquid. This transition can be observed as an endothermic event in differential scanning calorimetry (DSC). Reagent A within these particles then reacts with Reagent B to form solid solutions and intermetallics that are solids at T1. The formation of the solid solution and intermetallic reaction products can be observed as an exothermic event in DSC. Thus, the typical TLPS DSC “signature” is an endotherm followed by an exotherm. The diffusion and reaction of the Reagent A, available in liquid form, and Reagent B, in solid form, continues until the reagents are either fully depleted, there is no longer a liquid phase at the process temperature, or the reaction is quenched by cooling the mixture. After cooling, subsequent temperature excursions, even beyond the original melt temperatures, do not reproduce the original melt signature of the mixture. This is the DSC “signature” of a typical transient liquid phase sintered metal mixture.

As suggested above, however, TLPS is limited by the proportions of Reagent A and Reagent B, one of which may become exhausted during processing to the reaction products. When Reagent A is in excess, in prior art TLPS compositions comprising only a single particle type comprising Reagent A, the residual Facilitator metal (e.g., Bi) with less desirable properties is also in large proportion in the processed mixture.

Conversely, when Reagent B is in excess, once Reagent A in the liquified particles has been exhausted, the ability to rapidly form additional reaction products between Reagent A and Reagent B has been exhausted. Solid state interdiffusion between Reagent A and Reagent B may continue, but at a substantially reduced rate.

Prior art compositions teach the use of combining multiple Sn-based alloys with copper to effect TLPS processing at temperatures below the melting point of at least one of the alloys. Shearer et. al (U.S. Pat. No. 8,221,518, incorporated herein in its entirety by reference) teaches compositions including a mixture of particles, that includes between about 30 mass % and about 70 mass % of a first metallic particle, comprising at least one high melting point metal; between about 10 mass % and about 60 mass % of a second metallic particle comprising an alloy of a reactive, low melting point metal, and a carrier metal, wherein the reactive, low melting point metal is capable of reacting with the high melting point metal to form an intermetallic; between about 25 mass % and about 75 mass % of a third metallic particle comprising at least 40 mass % of the reactive, low melting point metal; and an organic vehicle. Shearer further teaches, “that by blending or mixing alloys, the proportion of residual carrying metal (e.g., Bi) with less desirable properties in the final processed TLPS network, can be controlled, while maximizing the amount of desirable intermetallic species formed.” However, Shearer teaches that the practical limit for replenishing Sn in the molten alloy from the non-molten alloy in-situ is a ratio of 1 part molten alloy per 3 parts non-molten alloy: “This phenomenon has been observed in TLPS compositions in which the proportion of non-molten to molten alloy phase was as high as 3:1, resulting in a substantial decrease in the proportion of undesirable Bi in the composition.”

The present disclosure is based on the observation that, contrary to the teachings of Shearer, a substantially lower ratio of molten (or liquid) alloy to non-molten alloy (in the range of about 1:20 to about 1:2) is not only feasible, but achieves better performance and reliability in some compositions and applications.

### Compositions of the Present Disclosure

The present disclosure thus provides compositions containing three types of metallic particles in an organic vehicle: Type 1A, Type 1B, and Type 2.

In the simplest terms, disclosed compositions consist of a particle mixture comprising:
a. 1 mass % and 10 mass % of Type 1A particles that are liquid at temperature T1, comprising at least one Reagent A;
b. 50 mass % and 80 mass % of Type 1B particles that are liquid at a temperature between T1 and T1 plus 100° C., comprising at least one Reagent A;
c. between about 5 mass % and about 45 mass % of Type 2 particles comprising at least one Reagent B; and
d. an organic vehicle;

wherein either Type 1A, or Type 1B, or both Type 1A and Type 1B particles further comprise at least one Facilitator element.

Reagent A is a reactive metal that, in liquid form, will rapidly interdiffuse with solid Reagent B to form solid solutions and intermetallic compounds that are solid at process temperature T1. Elements contemplated for use as Reagent A may be selected from the group consisting of Sn, In, Ga and combinations thereof. In some embodiments of the disclosure, Reagent A is Sn.

Facilitator elements are defined as elements that may be alloyed with Reagent A in either or both Type 1A and Type 1B particles for the purpose of reducing the liquidus temperature of said particles. For instance, when alloyed with Ag and Cu, the liquidus temperature of Sn may be reduced from 232° C. to 217° C. in the alloy form. Also, when Sn is alloyed with Bi or In, the liquidus temperature of elemental Sn may be reduced to 138° C. and 118° C. respectively in the eutectic alloy compositions. When non-eutectic alloys are formed, Facilitator elements may reduce the liquidus temperature of elemental Reagent A to a proscribed range in which the formation of a liquid phase is gradual, resulting in a ‘mushy’ phase until the liquidus temperature of the alloy is reached. Therefore, both the Facilitator element and its proportion in the alloy with Reagent A can be independently manipulated to achieve the desired result. Elements contemplated for use as Facilitators comprise Bi, In, Pb, Zn, Ag, Cu. Certain elements, such as In, Ag, and Cu; may be present in a composition as both Facilitators and Reagents serving in independent capacities in each particle type. The compositions are defined by the characteristics of the three distinct particle types and the elemental composition required to achieve each of those characteristics, rather than the elemental representation of the overall composition. The method of delivery of the elements through the defined three particle Types is critical to the disclosure.

Particle Type 1A comprises Reagent A and may be alloyed with at least one Facilitator element. At temperature T1 (discussed below), the Type 1A particles are liquid. In some embodiments of the disclosure, Type 1A particles comprise Sn and In in a eutectic alloy. The eutectic alloy of Sn and In has a liquidus temperature of 118° C., which is well below the very low assembly temperature of 140° C. desired by the electronics industry. Although In is expensive and has the propensity to form undesirable low-melting-temperature intermetallics, the low proportion of Type 1A particles in the disclosed compositions significantly mitigates these adverse characteristics.

Particle Type 1B comprises Reagent A and may alloyed with at least one Facilitator element. Particle Type 1B is liquid at a temperature less than T1 plus 100° C. In some embodiments of the disclosure, particle Type 1B comprises elements Sn and Bi in a non-eutectic composition. Bi is a very poor electrical and thermal conductor, is brittle, and, in the eutectic composition with Sn, has poor wetting characteristics that result in low quality assemblies. In the non-eutectic Sn60:Bi40 composition having a liquidus temperature of 170 degrees Celsius; however, the total proportion of Bi in the disclosed compositions remains relatively low and the wetting characteristics are much improved.

In some embodiments, a weight ratio of Type 1A particles to Type 1B particles is between about 1:20 and about 1:2. In other embodiments, the weight ratio of Type 1A particles to Type 1B particles is between about 1:18 and about 1:4.

A mixture of Type 1A particles containing eutectic SnIn and Type 1B particles containing non-eutectic SnBi in the proportions of the disclosed compositions thus advantageously exploits the favorable characteristics of both In and Bi while simultaneously mitigating their deleterious characteristics.

A mixture of Type 1A particles containing eutectic SnIn and Type 1B particles containing eutectic SnBi in the proportions of the disclosed compositions show favorable characteristics related to mechanical performance and reflow stability

Type 2 particles comprise Reagent B. Reagent B must be reactive with Reagent A at T1 through the mechanism of solid-liquid diffusion to form reaction products that are solids at T1. Elements contemplated for use as Reagent B are selected from the group consisting of Cu, Ag, Ni, and combinations thereof. Type 2 particles may further comprise alloying elements in addition to Reagent B.

Type 2 particles comprising Cu may be present in an about between about 5 mass % and about 45 mass %, more preferably between about 7 mass % and about 40 mass %, and most preferably 8 mass % to about 35 mass percent.

Cu is relatively inexpensive, plentiful, is compatible with the metallurgy typically used for electronic circuit elements, possesses a melting temperature over 1,000° C., is ductile, is readily available in a variety of powder forms, and is an excellent electrical and thermal conductor.

Ag is also specifically contemplated as Reagent B for use in the presently disclosed compositions, particularly in applications in which copper particles would be vulnerable to subsequent manufacturing processes (e.g., copper etching), or in cases in which the use of a noble metal would substantially decrease the need for organic flux to remove the metal oxides on the particles.

Ni is also relatively inexpensive, plentiful, is compatible with the metallurgy typically used for electronic circuit elements. When used in conjunction with Cu, Ni can suppress the formulation of Cu6Sn5 intermetallic that changes crystalline form at 186° C. with an associated change in density that may be deleterious to fatigue life. Ni also presents a lower coefficient of thermal expansion than Cu which may afford better compatibility with very low coefficient of thermal expansion adherends such as Si die.

In some embodiments of the disclosure, the Reagent A of Type 1A and Type 1B particles is the same metal and the particle types are differentiated by the alloyed Facilitator element and/or the proportion of the Facilitator element in the respective alloys.

In some embodiments, the composition of the Type 1A particles is eutectic, and the composition of the Type 1B particles is non-eutectic. In some embodiments, the Type 1B particles comprise tin alloys such as In52Sn48 (eutectic alloy). In some embodiments, the Type 1B particles comprise tin alloys such as Sn60Bi40 (a non-eutectic alloy) or Sn96.5:Ag3.0Cu0.5 (SAC 305). In some embodiments, the composition of the Type 1A particles is eutectic (In52:Sn48), and the composition of the Type 1B particles is eutectic (Sn42:Bi58).

The compositions may further comprise additional elements, either in particulate form, or as alloying elements in the Type 1 or Type 2 particulates. In some embodiments, such additional elements are included such that the reaction products of the composition as processed at T1 will have the optimum combination of attributes for the intended application. The attributes that may be considered typically encompass thermally stable resistance, ductility, high electrical and thermal conductivity, coefficients of thermal expansion similar to the surrounding materials, and the like.

Without wishing to be bound by any particular theory, it is believed that, as Reagent A in the liquified Type 1A particles is consumed in reaction products with Reagent B, additional Reagent A is supplied through the solubility of the Type 1B particles in the liquified Type 1A particles. Thus, the liquified Type 1A particles are continuously regenerated in-situ at T1 until the supply of Reagent A or Reagent B is exhausted.

All three particle types in the present compositions may be in the size range of 1-50 μm, and each may be present in either one or multiple particle size distributions within this range. It will be appreciated by those of skill in the art that the size range(s) of the Type 2 particles will impact the amount of Reagent B practically available for reaction with Reagent A at T1.

The organic vehicle may simply be a carrier for the metallic particles, serving to hold the mixture together for ease of application and to keep the various particles in close proximity to each other. More typically, a key attribute of the organic vehicle is to reduce and/or remove metallic oxides from the particle surfaces. Removal of the metallic oxides is referred to as fluxing and may be accomplished by a variety of chemical species known to those of skill in the art, including organic acids and strong bases. Other attributes of the organic vehicle would be specific to the application. For instance, an application in which the presently disclosed metallic compositions are employed as a solder paste replacement, the entire organic vehicle may be formulated to volatilize during processing. In applications in which present metallic compositions are employed in adherent coatings on nonmetallic surfaces, the organic vehicle may comprise components that would serve an adhesive function. Therefore, aside from the necessity for a fluxing component, the organic vehicle may comprise a wide variety of organic constituents.

The present compositions may be prepared by weighing out the proscribed proportions of the three types of metallic particles, admixing them, and blending with the organic vehicle to form a paste-like composition. Techniques for such formulation blending are well known by those of skill in the art. All of the particles and the components of the organic vehicle are commercially available from multiple sources.

Following preparation, the composition can then be used in a variety of assembly applications. For example, after processing at a temperature at or about T1 for a duration of less than 20 minutes, a semiconductor package may be mechanically joined and electrically interconnected to a metallized substrate using the present compositions. To achieve the reduction in warpage issues that are problematic to the electronics industry in these types of assemblies, T1 is preferably less than 150° C., and more preferably less than or equal to 140° C.

Upon completion of processing at T1, the joints formed from the presently disclosed compositions are electrically and mechanically stable through subsequent thermal excursions.

Additional examples of applications in which the presently disclosed compositions are useful are connecting semiconductor dies to packaging elements, connecting packaged semiconductor components to printed circuit boards, connecting other discrete components to electronic substrates, forming connections between stacked die, to electrically interconnect electrical subsystems through interposer structures, and the like.

The above-described compositions can be applied using various techniques, including, but not limited to, needle dispensing, stenciling, screen printing, ink jetting, extrusion, casting, spraying or other methods that would be known to those of skill in the art. Once applied, the described compositions are thermally processed in an oven, on a hot plate, in a reflow furnace, or by other means typically employed for the processing of solder or filled organic adhesives. The specific thermal process conditions are dependent upon the application as well as selection of the TLPS system and any organic vehicle constituents.

### EXAMPLES

Reference will now be made to more specific embodiments of the present disclosure and experimental results that provide support for such embodiments. The examples are given below to more fully illustrate the disclosed subject matter and should not be construed as limiting the disclosed subject matter in any way.

### Example 1

A series of compositions were prepared by weighing and admixing formulation components in the proportions detailed in Table 1:

TABLE 1

| Particle | | Comparison | Formu- | Formu- |
|---|---|---|---|---|
| type | Composition | Formulation 1 | lation 2 | lation 3 |
| Type 1A | In52Sn48 | 28.6 | 5 | 5 |
| Type 1B | Sn60Bi40 | 28.6 | 62 | 44 |
| Type 1B | Sn96.5:Ag3.0Cu0.5 | | | 19 |
| Type 2 | Cu | 42.8 | 33 | 32 |
| Organic | Carboxylic acid | 4.5 | 4.5 | 4.5 |
| vehicle | trialkanolamine salt | | | |
| | flux | | | |
| Organic | Glycol ether diluent | 4.5 | 4.5 | 4.5 |
| vehicle | | | | |
| Ratio | Type 1A:Type 1B | 1:1 | 1:12.4 | 1:12.6 |

BGA assemblies were prepared with the compositions by applying each of the compositions to a circuitized substrate using a stencil with apertures corresponding to the BGA pattern and its receiving circuit pads, placing the BGA packages onto the patterned deposit, subjecting the BGA-paste-substrate assemblies to thermal exposure under nitrogen with a peak temperature and total duration of 15 minutes.

The circuit pattern of the receiving substrate is designed such that all the balls must be electrically connected to the substrate or the test pattern, when probed, will read electrically open.

25% of the assemblies constructed with Comparison Composition 1 were electrically open as processed. Both of Formulations 2 and 3 had 100% electrical connection.

Eight assemblies of each paste and each BGA were initially prepared, electrically probed, and then inserted into a thermal shock chamber set to run from −40° C. to 125° C. The assemblies were removed from the thermal shock chamber at 250, 500, 750 and 1000 cycles and were electrically probed with the following results in Table 2:

TABLE 2

| | BGA 192 | | | BGA 196 | | |
|---|---|---|---|---|---|---|
| | Comp | | | Comp | | |
| | Form. 1 | Form. 2 | Form. 3 | Form. 1 | Form. 2 | Form. 3 |
| Cycles | (Ω) | (Ω) | (Ω) | (Ω) | (Ω) | (Ω) |
| 0 | 0.56 | 0.46 | 0.47 | 1.03 | 0.67 | 0.7 |
| 250 | fell off | 0.46 | 0.83 | fell off | 0.6 | 0.98 |
| 500 | | 0.48 | 1.1 | | 0.86 | 1.47 |
| 750 | | 0.5 | 1.37 | | 1.12 | 1.57 |
| 1000 | | 0.51 | 1.37 | | 1.26 | 1.91 |

As can be seen in the data table, assemblies employing inventive compositions 2 and 3 maintained relatively stable electrical performance through the stringent air-to-air thermal shocks; whereas comparison composition 1 had both higher initial resistance than the inventive composition assemblies and lost mechanical integrity by 250 shocks.

### Example 2

A series of compositions were prepared by weighing and admixing formulation components in the proportions detailed in Table 3:

TABLE 3

| | | | | | Comparison | Comparison |
|---|---|---|---|---|---|---|
| Particle | | Formulation | Formulation | Formulation | Formulation | Formulation |
| type | Composition | 4 | 5 | 6 | 7 | 8 |
| Type | In52Sn48 | 5 | 5 | 5 | 35 | 35 |
| 1A | | | | | | |
| Type | Sn60Bi40 | 62 | | | | |
| 1B | | | | | | |
| Type | Sn42Bi58 | | 62 | | | |
| 1B | | | | | | |
| Type | Sn80Bi20 | | | 62 | | |
| 1B | | | | | | |
| Type 2 | Cu | 33 | 33 | 33 | | 65 |
| | Ag | | | | 65 | |
| Organic | Carboxylic | 4.5 | 4.5 | 4.5 | 4.5 | 4.5 |
| vehicle | acid | | | | | |
| | trialkanolamine | | | | | |
| | salt flux | | | | | |
| Organic | Glycol ether | 4.5 | 4.5 | 4.5 | 4.5 | 4.5 |
| vehicle | diluent | | | | | |
| Ratio | Type 1A:Type 1B | 1:12.4 | 1:12.4 | 1:12.4 | N/A | N/A |

| | | | | | |
|---|---|---|---|---|---|
| Room temperature shear | 3.4 kg | 2.9 kg | 2.3 kg | 0.10 kg | 0.72 kg |
| strength of 0805 resistor | | | | | |
| assembly | | | | | |
| 100° C. shear strength of | 1.9 kg | 0.4 kg | 0.5 kg | 0.02 kg | 0.11 kg |
| 0805 resistor assembly | | | | | |

Assemblies of the above compositions were prepared by applying each paste through a stencil with an aperture pattern that corresponds to a group of 0805 chip resistors onto a copper substrate, placing the terminations of 0805 chip resistors into the patterned paste deposits, and heating in a nitrogen convention reflow furnace to 140° C. for about 15 minutes.

After the thermal treatment of each assembly was completed, the resultant joints were sheared at room and elevated temperature to characterize the relative strength of the joints. The results are summarized in Table 3.

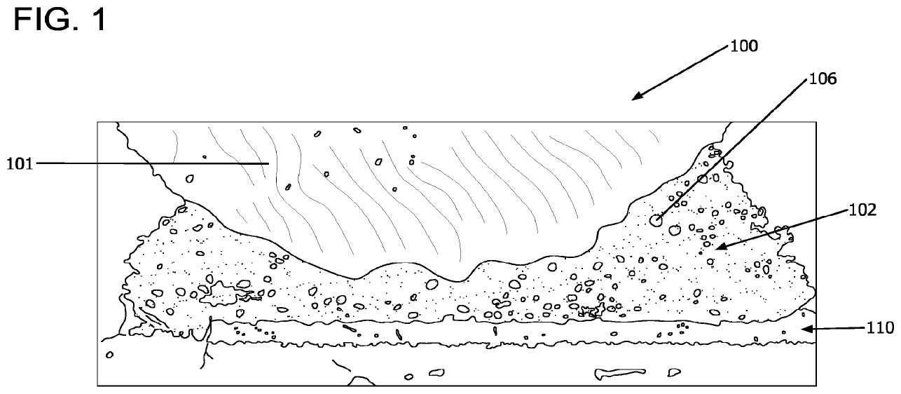

FIG. 1 is a cross-sectional optical image of an embodiment composition connecting a ball-grid-array (BGA) electronic package 100 to an electronic substrate with copper terminations. The joint in the cross-sectional image was formed using a nitrogen convection furnace at a peak process temperature of 140° C. Each ball 101 comprises tin solder such as SAC 305. The joint of conductive paste 102 comprises copper particles 106 and conductively joins the ball 101 and the copper termination 110.

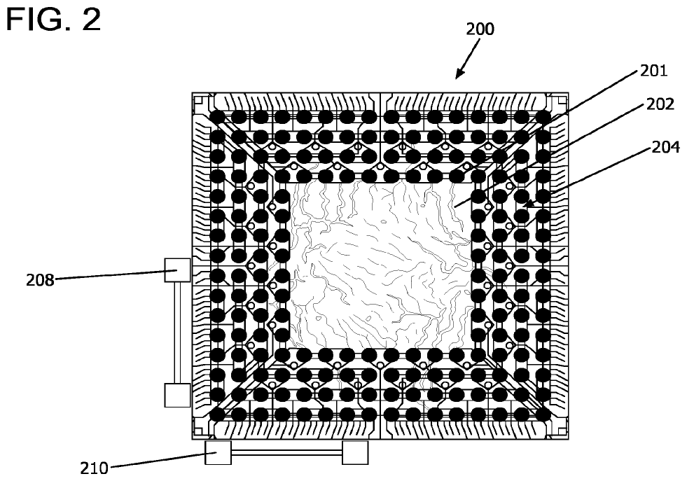

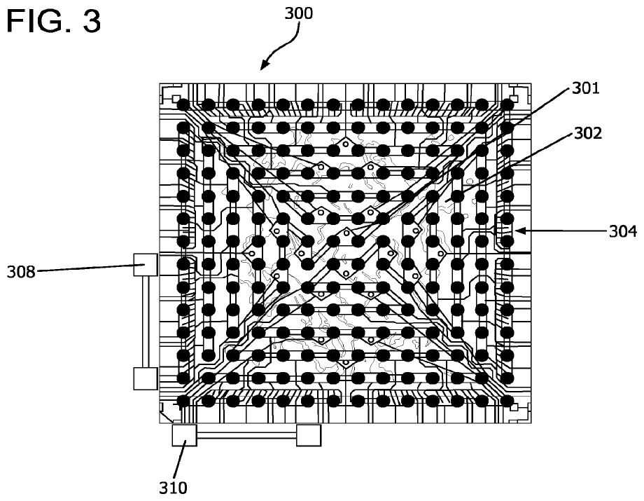

FIG. 2 and FIG. 3 are x-ray images of large-scale semiconductor packages 200, 300 attached to substrates in a 140° C. process using formulation 4, which is also used in the embodiment shown in FIG. 1. These ball-grid-array (BGA) packages are referred to peripheral array and full array respectively. In high temperature assembly large-scale packages of these types tend to warp, thus preventing formation of a joint to some of the balls in the array-particularly in the corners. The x-ray images of assemblies made with the present compositions clearly indicate that joints were successfully formed across the entirety of both the peripheral and full array. The 16×16 peripheral array 200 comprises balls 201 joined to circuitry 204 and copper terminations via conductive paste 202. Circuit terminals or probe points 208 and 210 are shown at the periphery of the BGA 200. The 14×14 full array 300 comprises balls 301 joined to circuitry 304 and copper terminations via conductive paste 302, and probe points 308, 310.

### Example 3

Three formulations were prepared: A conventional solder paste of the eutectic composition Bi58:Sn42, invention formulation #9 and #10. The formulations were prepared as in the previous examples using the proportions in Table 4.

TABLE 4

| Particle | | | Invention | Invention |
|---|---|---|---|---|
| Type | | Control | formulation 9 | formulation 10 |
| 1A | In52:Sn48 | | 5 | 4.6 |
| 1B | Sn60:Bi40 | | | 56.4 |
| 1B | Sn42:Bi58 | 91 | 76 | |
| 2 | Cu | | 10 | 30 |
| Organic | Carboxylic acid | 4.5 | 4.5 | 4.5 |
| vehicle | trialkanolamine | | | |
| | flux | | | |
| Organic | Glycol ether | 4.5 | 4.5 | 4.5 |
| vehicle | diluent | | | |
| Ratio of | | 0:1 | 1:15.2 | 1:12.3 |
| 1A:1B | | | | |

Each of the formulations was applied to a patterned substrate using a stencil mask that corresponded to both the pattern on the substrate and a pattern of solder balls on a BGA semiconductor package. The BGA packages were placed onto the patterned pastes such that the solder balls were in contact with the paste deposits. Once placed, the BGA-paste-substrate assemblies were subjected to a thermal treatment in a tunnel reflow furnace equipped with nitrogen as a cover gas. The thermal treatment had a peak temperature of 140 C for formulation 9 and 165 C for the control solder paste in order to melt the type 1A and type 1B particles such that a joint could be formed between the BGAs and substrates.

Once thermally processed, the assemblies were subjected to drop testing. The drop test consisted of an eight foot section of plumbing pipe vertically oriented through which each assembly was repeatedly dropped on edge until the BGA was dislodged.

The diameter of the plumbing pipe was selected such that the assemblies remained in the on-edge presentation for the duration of each drop cycle. Electrical continuity was tested every 5 drops. The mechanical results were as follows:

| Sample | Control | Formulation #9 | Formulation #10 |
|---|---|---|---|
| # of drops to failure | 35 | 35 | 5 |

This experiment demonstrates that invention formulations can provide equivalent mechanical performance to conventional solder at a substantially lower peak process temperature.

### Example 4

Formulation 9 of the previous example was again used to create BGA-paste-assemblies by the same thermal treatment used in the previous example.

It is common industry practice to subject joints formed by such thermal processes to additional thermal process cycles to determine if the connection remains stable.

In the assemblies built with Formulation #9 the resistance was unchanged after an additional thermal process cycle.

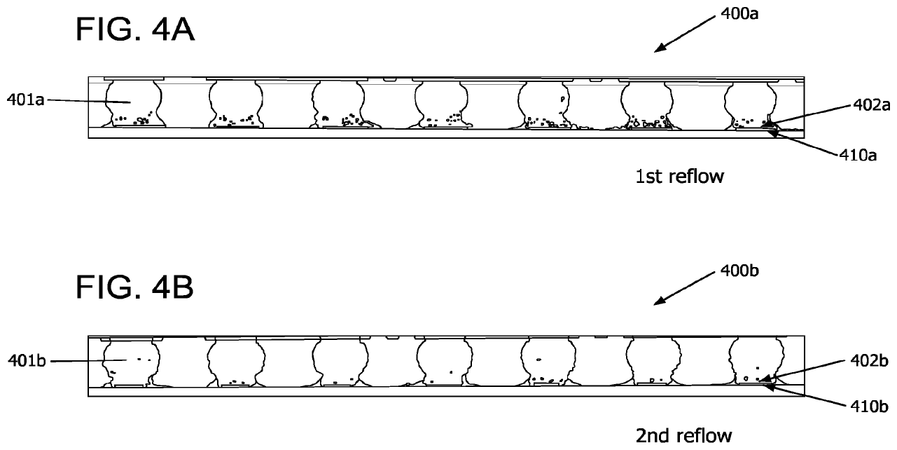

Cross sections of assemblies as-processed (illustrated in FIG. 4A) and after an additional reflow cycle (illustrated in FIG. 4B) do not show a change in the morphology of the joint which is further indicative of stability. Each ball 401a, 401b comprises tin solder such as SAC 305. The joint of conductive paste 402a, 402b comprises copper particles (not shown) and conductively joins the ball 401a, 401b and the copper termination 410a, 410b.

As one can readily ascertain, the use of the presently disclosed range of metal particle Type 1A to provide a full liquid phase at T1, but leveraging the superior joint formation capability of metal particle Type 1B offers mechanically strong joints at both room and elevated temperature when the composition is process at the industry-desire temperature of 140° C. In contrast, formulations that rely exclusive on Type 1A metal particles provide inferior joints at both room and elevated temperature when processed at 140° C.

While this invention has been described with respect to these specific examples, it should be clear that other modifications and variations would be possible without departing from the spirit of this invention.

1. A particle mixture composition comprising:
a) between about 1 mass % and about 10 mass % of Type 1A particles that are liquid at a temperature T₁, the Type 1A particles comprising at least one Reagent A;
b) between about 50 mass % and about 80 mass % of Type 1B particles that are liquid at a temperature between T₁ and T₁ plus 100° C., the Type 1B particles comprising at least one Reagent A;
c) between about 5 mass % and about 45 mass % of Type 2 particles comprising at least one Reagent B;
and
d) an organic vehicle;
wherein Reagent A and Reagent B are metals, and wherein either Type 1A, or Type 1B, or both Type 1A and Type 1B particles may further comprise at least one Facilitator element.

2. The composition of claim 1, wherein Reagent A is selected from the group consisting of Sn, In, and Ga, and combinations thereof.

3. The composition of claim 1, wherein Reagent A is selected from the group consisting of Sn, In, and combinations thereof.

4. The composition of claim 1, wherein Reagent A is substantially Sn.

5. The composition of claim 1, wherein Reagent B is selected from the group consisting of Cu, Ag, Ni, and combinations thereof.

6. The composition of claim 1, wherein Reagent B is substantially Cu.

7. The composition of claim 1, wherein Facilitator elements are selected from the group consisting of Bi, In, Pb, Zn, and combinations thereof.

8. The composition of claim 1, wherein Facilitator elements are selected from the group consisting of of Bi, In, and combinations thereof.

9. The composition of claim 1, wherein Type 1A particles comprise Facilitator element In.

10. The composition of claim 1, wherein Type 1B particles comprise Facilitator element Bi.

11. The composition of claim 1, wherein said organic vehicle comprises a thermosetting adhesive resin.

12. The composition of claim 1, wherein Reagent A, in liquid form, reacts with Reagent B, in solid form, at temperature T₁, wherein T₁ is in the range between about 80° C. and about 150° C.

13. The composition of claim 1, wherein Type 1A particles comprise an alloy of In and Sn.

14. The composition of claim 13, wherein Type 1A particles comprise a eutectic alloy of In and Sn.

15. The composition of claim 1, wherein Type 1A particles comprise an alloy of Sn and Bi.

16. The composition of claim 15, wherein Type 1A particles comprise a eutectic alloy of Sn and Bi.

17. The composition of claim 12, wherein the reaction products of Reagent A and Reagent B are solid solutions and intermetallics that are solid at T₁.

18. A method for fabricating the composition of claim 1, the method comprising: combining a predetermined ratio of Type 1A particles, Type 1B particles, Type 2 particles, and the organic vehicle to form a mixture of components thereby.

19. A method for making an electrically and thermally conductive interconnection comprising:
a) applying an amount of the composition of claim 1 to an assembly of at least two parts, wherein the at least two parts are to be electrically interconnected;
b) heating the composition to a temperature T₁, wherein T₁ is between about 80° C. and about 150° C.,
to obtain an electrically and thermally conductive interconnection thereby.

20. A particle mixture composition comprising:
a) Type 1A particles that are liquid at a temperature T₁, comprising at least one Reagent A;
b) Type 1B particles that are liquid at a temperature between T₁ and T₁ plus 100° C., comprising at least one Reagent A;
c) Type 2 particles comprising at least one Reagent B;
and
d) an organic vehicle;
wherein Reagent A and Reagent B are metals, and wherein either Type 1A, or Type 1B, or both Type 1A and Type 1B particles may further comprise at least one Facilitator element,
and wherein a weight ratio of Type 1A particles to Type 1B particles is between about 1:20 and about 1:2.

21. The composition of claim 20, wherein Reagent A comprises Sn or Reagent B comprises Cu.

22. The composition of claim 20, wherein the Type 1A particles comprise an alloy of In and Sn.

23. The composition of claim 22, wherein Type 1A particles comprise a eutectic alloy of In and Sn.

24. The composition of claim 20, wherein the Type 1B particles comprise an alloy of Sn and Bi.

25. The composition of claim 24, wherein Type 1B particles comprise a eutectic alloy of Sn and Bi.

26. The composition of claim 20, wherein the weight ratio of Type 1A particles to Type 1B particles is between about 1:18 and about 1:4.
